(19) United States
(12) Patent Application Publication
(10) Pub. No.: US 2026/0351925 A1
(43) Pub. Date: Nov. 5, 2026

(54) OPTICAL FREQUENCY COMB

(71) Applicants: DUBLIN CITY UNIVERSITY, Dublin (IE); TRINITY COLLEGE DUBLIN, Dublin (IE)

(72) Inventors: Prince ANANDARAJAH, Swords (IE); Aleksandra KASZUBOWSKA, Swords (IE); Praywal DODDABALLAPURA, Dublin (IE)

(73) Assignees: DUBLIN CITY UNIVERSITY, Dublin (IE); TRINITY COLLEGE DUBLIN, Dublin (IE)

(21) Appl. No.: 19/112,470

(22) PCT Filed: Sep. 12, 2023
(86) PCT No.: PCT/EP2023/075037

§ 371 Date: Mar. 17, 2025

(30) Foreign Application Priority Data
Sep. 16, 2022 (GB) 2213655.0

(51) Int. Cl. H01S 5/062

(52) U.S. Cl. CPC H01S 5/062

(57) ABSTRACT

An apparatus and method for generating a wavelength tuneable broadband optical frequency comb. A suitable apparatus includes a master laser unit and a gain switched (semiconductor Fabry Perot) slave laser. The gain-switched slave laser is configured to generate an optical output including multiple (longitudinal) emission modes, while the master laser unit is configured to generate a seed signal including a set of correlated tones (based on a source optical frequency comb). Seeding of the gain switched slave laser by the seed signal optically injection locks the emission modes of the slave laser unit (and simultaneously excites at least some of the laser modes) to generate a coherent wideband optical frequency comb.

### FIELD OF THE INVENTION

The present disclosure relates to optical frequency combs. In particular, the present disclosure relates to an apparatus and method for generating a wavelength tuneable broadband optical frequency comb.

### BACKGROUND

An optical frequency comb (OFC) is a laser source comprising equidistant and phase correlated lines. Such properties make the OFC invaluable in a wide range of applications such as spectroscopy, atomic clock, steganography, spectrally efficient optical communications, millimetre wave (mmW)/terahertz (THz) generation, and many more.

The optimum characteristics of an OFC depend on the target application, although generally accepted minimum requirements are a large number of lines, a high degree of phase correlation, low noise (phase and intensity), and tunability in free spectral range (FSR) and emission wavelengths. Amongst several semiconductor-based OFC generation schemes, an externally injected gain-switched laser (EI-GSL) offers simplicity, tunability, and cost-effectiveness. However, the number of OFC lines generated is limited by the restricted modulation bandwidth of the semiconductor laser used (usually spans about 1 nanometre ‘nm’). The small bandwidth significantly limits the range of application sectors that the GSL OFCs can be employed in.

To address this challenge, several photonically integrable expansion schemes have been investigated, including the use of electro-optic phase modulators, cascaded gain-switched FP lasers, dual-mode FP lasers, and mutually injection-locked GSLs. These schemes are effective but limited to an expansion factor of up to 3 (i.e., up to about 3 nm).

Hence it is now desired to provide an OFC with greater bandwidth as an alternative to previously available designs.

### SUMMARY

The present invention is defined according to the independent claims. Additional features will be appreciated from the dependent claims and the description herein. Any embodiments which are described but which do not fall within the scope of the claims are to be interpreted merely as examples useful for a better understanding of the invention.

The example embodiments have been provided with a view to addressing at least some of the limitations that are encountered with current OFCs, whether those difficulties have been specifically mentioned above or will otherwise be appreciated from the discussion herein. In particular, it is an aim of the present techniques to significantly increase the achievable expansion factor of an OFC—i.e., improve the bandwidth.

Accordingly, in one aspect of the invention there is provided an apparatus for generating a wavelength tuneable broadband optical frequency comb. The apparatus comprises a master laser unit and a gain switched (semiconductor Fabry Perot) slave laser. The gain-switched slave laser is configured to generate an optical output comprising multiple (longitudinal) emission modes. The master laser unit is configured to generate a seed signal comprising a set of correlated tones (based on a source optical frequency comb). Seeding of the gain switched slave laser by the seed signal optically injection locks the emission modes of the slave laser unit (and simultaneously excites at least some of the laser modes) to generate a coherent wideband optical frequency comb. Not only is the generated frequency comb wideband, but it is highly correlated in phase, making it suitably for a wide range of applications that present EI-GSL based OFCs are not; for example, data encoding and mmW applications, among others.

In the present techniques, generating the coherent wideband optical frequency comb comprises exciting at least 2 longitudinal modes of the gain switched slave laser, and further preferably at least 6 longitudinal modes. The more modes that are excited, the greater the bandwidth of the generated optical frequency comb. The number of modes which are excited depends on a laser power of the seed signal, and so said power may be suitably tuned to control the bandwidth of the resultant frequency comb.

Suitably the seed signal may comprise an optical frequency comb generated by a light source configured as part of the master laser unit, and accordingly the set of correlated tones of the seed signal may comprise amplified optical frequency comb tones (at least two) of the source optical frequency comb. The set of correlated tones may also comprise aspects of additional spectral components specifically added to the optical frequency comb source signal. Suitably, in some examples, the master unit comprises a dual-stage active demultiplexer configured to receive the optical frequency comb generated by the optical frequency comb light source to amplify the initial comb tones and generate the additional spectral components.

In one example such a dual-stage active demultiplexer may comprise a first laser configured to receive the optical frequency comb generated by the light source, and a second laser configured to receive optical output from the first laser, such that the resultant seed signal comprises a number of spectral components based on a power of the first laser and second laser. In one example, the set of correlated tones comprises a pair of amplified optical frequency comb tones and four wave mixed spectral tones.

In some examples the apparatus also comprises a phase modulator configured to receive the coherent wideband optical frequency comb to generate a substantially contiguous optical frequency comb. That is, the phase modulator removes, or at least smooths out, minima between adjacent excited modes of the gain-switched slave laser, thereby expanding the usable bandwidth of the generated optical frequency comb.

In a related aspect of the invention there is similarly provided a method of generating a wavelength tuneable broadband optical frequency comb. The method suitable comprises generating an optical seed signal (from a source optical frequency comb) comprising a set of correlated tones, generating a gain switched optical slave signal comprising multiple emission modes, and injection locking the gain switched optical slave signal using the optical seed signal to generate a coherent wideband optical frequency comb. Injection locking the gain switched optical slave signal using the optical seed signal to generate a coherent wideband optical frequency comb comprises exciting at least 2 longitudinal modes of the gain switched slave laser, and preferably at least 6 longitudinal modes.

In some examples generating the optical seed signal comprises dual stage active demultiplexing of an optical frequency comb generated by a light source, which allows for the selection and amplification at least two comb tones of the optical frequency comb output by the light source, and the generation of additional spectral components in the optical seed signal (such as by four wave mixing). The more spectral components that are present in the seed signal, the more modes of the gain-switched laser it is possible to excite.

In some examples, the (amplified) at least two comb tones are selected for amplification based on separation frequency of the emission modes of the optical slave signal. Preferably the separation of the selected and amplified at least two comb tones substantially matches the separation frequency of the emission modes of the optical slave signal, but in some cases it can be offset which provides control over a shape of the resultant OFC; in particular, flattening the expanded coherent wideband optical frequency comb by optimising the separation of the selected and amplified at least two comb tones with respect to a mode separation of the optical slave signal.

The method may also comprise making the generated coherent wideband optical frequency comb more contiguous using a phase modulator.

In another related aspect of the invention there is provided a photonic circuit comprising the aforementioned apparatus and/or method.

### BRIEF DESCRIPTION OF THE DRAWINGS

For a better understanding of the present disclosure reference will now be made to the accompanying drawings, in which:

FIG. 1 shows a schematic of an example apparatus and corresponding technique for generating a wavelength tuneable broadband optical frequency comb;

FIG. 2 shows one example embodiment of a broadband wavelength tuneable optical frequency comb generator;

FIG. 3 shows example output signals for the apparatus of FIG. 2 based on experimental results;

FIG. 4 shows superimposed optical spectra of an example expanded comb and various demultiplexed tones with various frequency separations, which can be used as (a) carriers (6.25 G-12.5 G-25 GHz separation) and/or (b) for a heterodyne process (illustrating 175 G, 700 G, 875 GHz separation).

### DETAILED DESCRIPTION

At least some of the following example embodiments provide an improved optical frequency comb (OFC); in particular, a broadband OFC. Many other advantages and improvements will be discussed in more detail herein.

By way of introduction, broadly the presently described techniques enable the generation of an expanded optical frequency comb (OFC) using a gain switched Fabry-Pérot (FP) laser that is optically injected with two phase correlated signals.

The technique involves externally injecting a gain-switched FP laser (multi-mode laser with uncorrelated phase in each of the modes) with a unique correlated signal generated by a dual-stage active demultiplexer (DS-AD). Optical injection locking (OIL) simultaneously locks two longitudinal modes of the gain-switched FP laser. The OIL of these two modes and the newly created modes (explained further below) enables correlating all the modes of the multi-moded FP laser to generate a broadband OFC. The presently described broadband OFC opens up a plethora of applications that can be potentially explored, while benefiting from the attractiveness of the simplicity of the proposed scheme. An added bonus is that the architecture to implement the present techniques can be realised as a photonic integrated circuit (PIC).

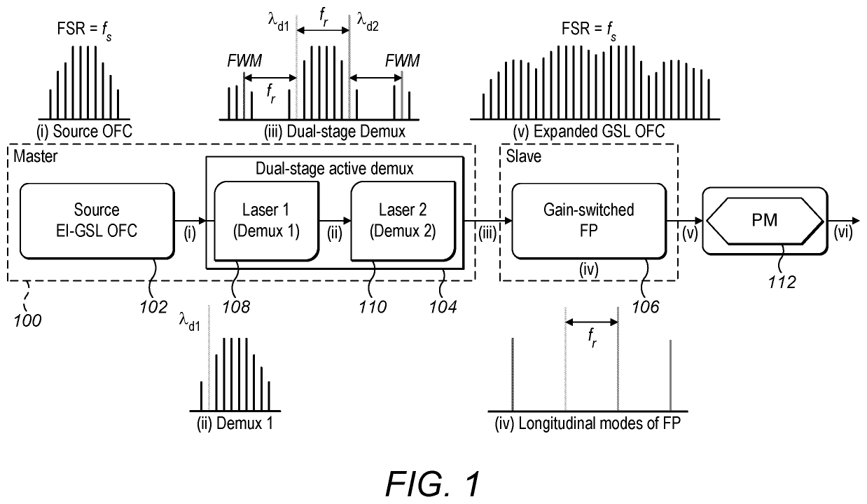

FIG. 1 shows a schematic of an example apparatus 10 (and correspondingly applied method) for generating a wavelength tuneable broadband optical frequency comb, based on a master-slave laser configuration.

The apparatus 10 comprises a master laser unit 100 configured to generate a seed signal comprising a set of correlated tones (FIG. 1(i)-(iii)), and a gain switched slave laser 106 configured to generate an optical output comprising multiple emission modes (FIG. 1(iv)), which is suitably arranged to be seeded by the seed signal generated by the master laser unit. Seeding of the slave laser 106 by the seed signal optically injection locks the emission modes of the slave laser unit to generate a coherent wideband optical frequency comb (FIG. 1(v)).

In more detail, the master unit 100 comprises a source optical frequency comb (OFC) 102 with a free spectral range (FSR) of fₛ (FIG. 1(i)). The source OFC 102 is injected into a dual-stage active demultiplexer (DS-AD) 104 (FIG. 1(ii)), the output of which is subsequently injected into the gain-switched slave laser 106; preferably the gain-switched slave laser 106 is a Fabry-Pérot laser.

The general working principles of the DS-AD 104 can be found in the art, for example at the Journal of Lightwave Technology, vol. 39, no. 24, pp. 7771-7780, 2021. In the present examples, the DS-AD 106 is used to demultiplex (i.e., select) of two OFC tones λ_{d1} and λ_{d2} with a desired frequency separation fᵣ+Δf. In preferred embodiment, the separation is matched to that of the longitudinal mode spacing of the slave laser 106. The DS-AD comprises 106 comprises two lasers, here labelled Demux1 and Demux2, but which may otherwise be termed a first laser 108 and second laser 110.

Suitably, injection of Demux 1 into Demux 2 results in four-wave mixing (FWM) inside the cavity of Demux 2 leading to the generation of new spectral components that are separated from λ_{d1} and λ_{d2} by fᵣ [13]. Thus, in the present example as illustrated in FIG. 1(iii), the output of the DS-AD 106 contains two demultiplexed and amplified OFC tones, and newly generated FWM tones.

As will be appreciated by those in the art, four wave mixing arises from non-linearities in lasing within the cavity of the second laser 110 (Demux2). The degree of non-linearity, and therefore number of new spectral components which are created, is also dependent on the injected laser power; other cavity parameters such as size, material, etc, can also impact the non-linearity. That is, a number of spectral components of a signal output from the DS-AD 104 may be suitably varied by varying the laser power within it (e.g., of Demux1). This allows control over the spectral signal which is subsequently used to injection lock the slave laser 106 (and therefore may aid in expanding or narrowing the desired final frequency comb).

Suitably, the output of the DS-AD 104—i.e., comprising the amplified tones and newly created spectral components—is injected into the slave laser 106 which is preferably gain-switched at fₛ (FIG. 1(iv)). Thus, the in-series combination of OFC source 102 and DS-AD 104 generates the seed signal (FIG. 1(iii)) comprising the set of correlated tones (here the two amplified tones and FWM tones) which are used to seed the gain-switched slave laser 106. Here correlated may be taken to mean that the tones are correlated in phase (e.g., regularly spaced), and so would produce a coherent signal when beat together.

The demultiplexed OFC lines and the FWM components simultaneously injection lock adjacent longitudinal modes of the gain-switched FP laser. The injection locking of multiple longitudinal modes of the FP results in the generation of a coherent wideband gain-switched OFC at FSR of fₛ. In particular, injection locking excites several longitudinal modes of the FP laser, leading to the generation of coherent comb lines across each mode.

Optionally, the output from the slave laser 106 may be passed through a through a phase modulator (PM) 112 to generate a contiguous broadband gain-switched OFC at FSR of fₛ (FIG. 1(vi)).

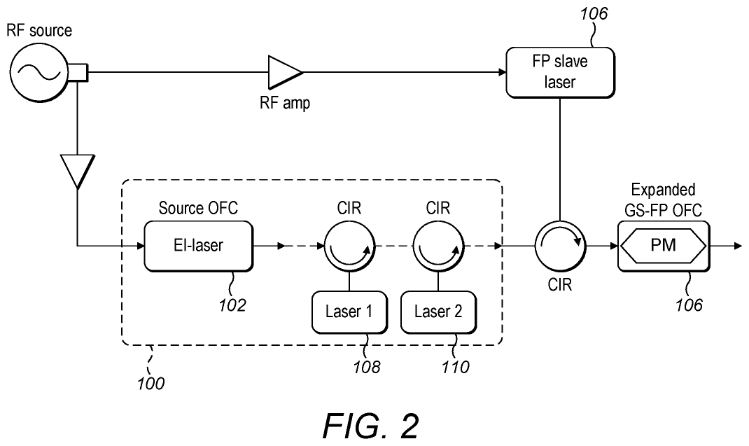

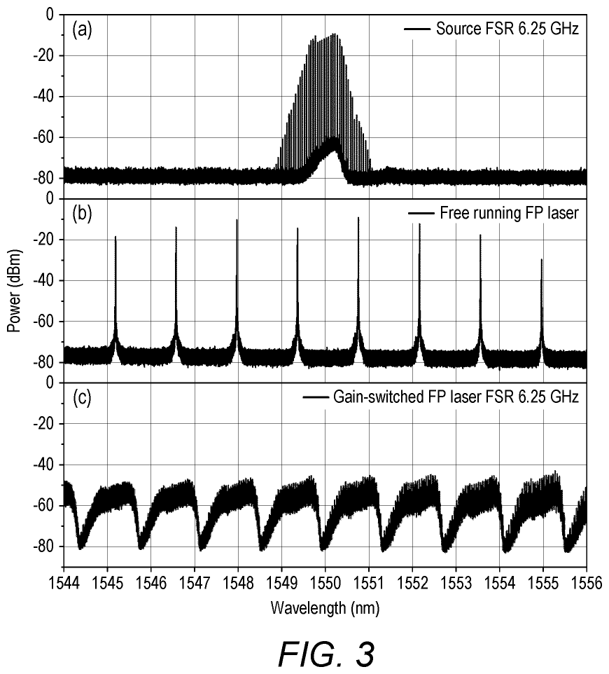

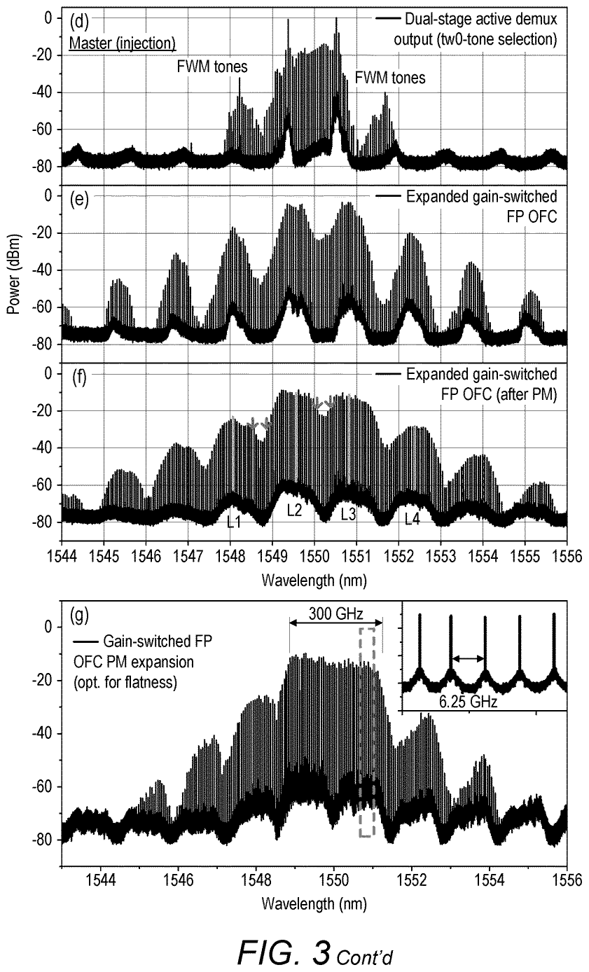

FIG. 2 shows an example implementation of the apparatus 10/method of FIG. 1—i.e., a broadband wavelength tuneable OFC generator—while FIG. 3 shows example outputs/signals at each stage of the technique.

In the present example, the source OFC 102 is an EI-GS which generates an output as shown in FIG. 3(a), with an FSR of 6.25 GHZ (fₛ). It emits 13 coherent tones (within 5 dB from the spectral peak) spanning over 81.25 GHz. This source OFC is injected into a semiconductor laser-based DS-AD 104 formed from two commercially available discrete mode (DM) lasers and two 3-port optical circulators which enable optical injection in series.

Two OFC tones (20 dB below the spectral peak) separated by 150 GHz, are demultiplexed/amplified with the aid of the DS-AD. As mentioned above, new spectral components are formed due to FWM in Demux 2, as shown in the optical spectrum in FIG. 3(d). These amplified OFC and the FWM tones at the output of the DS-AD, act as the master seed signal.

An FP laser diode encased in a TEC-controlled butterfly package is used as the slave laser 106. The optical spectrum of the free-running FP laser is shown in FIG. 3(b) and has a longitudinal mode spacing of ~160 GHz. This particular signal is by a laser exhibiting a threshold current (Iₜₕ) of 10 mA and biased at 6×Iₜₕ, emitting an average output power of 8 dBm. The slave FP laser 106 is then gain-switched at 6.25 GHz (with the same RF source used for the source OFC 102). FIG. 3(c) shows the optical spectrum of the gain-switched FP laser, where the absence of discernible comb lines can be observed, owing to a large timing jitter due to the gain-switching process. Subsequently, the output of the DS-AD is injected into the gain-switched FP laser, which results in injection locking of multiple FP modes with the demultiplexed lines (corresponding to λ_{d1} and λ_{d2}) and FWM tones. The optical injection from the DS-AD locks the phase of the successive gain-switched FP pulses and introduces a pulse-to-pulse coherence, leading to the generation of discernible coherent OFC lines across several FP modes.

The strong injection from the DS-AD into the FP laser also stimulates the FWM process inside the FP cavity. In this example this results in the simultaneous locking of six gain-switched FP modes, as shown in FIG. 3(e), leading to the generation of comb lines on each of these modes (i.e., there are six modes which have coherent and usable comb lines). It will be appreciated, however, that varying the power of the seed signal will vary the number of FP modes which are excited due to non-linearities of the FP laser cavity. Thus, generally, although the present example shows six modes being excited/locked, the present techniques could equally be applied within a suitable system to lock only two modes, or indeed lock more than 6 modes. In comparison to the source OFC, the generated OFC may

As seen from FIG. 3(e), the initial output of the seeded/injection locked FP laser 106 is non-contiguous—that is, there are significant minima between some adjacent modes. While this is perfectly perfunctory for applications of the OFC, it may cause problems with others.

Suitably, in some example implementations, the output of the gain-switched FP OFC can be further expanded by passing it through a phase modulator to achieve a gain-switched OFC spanning over 875 GHz, as shown in FIG. 3(f)—here the phase modulator is characterised by V_{π}=4 V, driven with 13 V at 12.5 GHz. Taking the source OFC as having a width of approximately 1 nm, it can be seen that the generated (and now contiguous) gain-switched OFC is expanded by a factor of at least 8, now spanning over at least 8 nm. The generated comb lines are highly correlated with each other and portray a low intensity and phase noise (linewidth); features that are highly attractive to all the above-mentioned applications.

Furthermore, the expansion of the OFC can be optimised for flatness or/and wide span, according to the target application. To demonstrate this, the expansion is tuned to achieve a continuous flat OFC spectrum over 300 GHz (within 5 dB) with an optical carrier to noise ratio (OCNR) >50 dB, as depicted in FIG. 3(g). This is done by optimising the separation between the two tones used for injection locking the FP laser (fᵣ reduced by 25 GHz). Such an expanded comb, optimised for flatness, could be utilised for superchannel-based optical networks. On the other hand, the wider comb (875 GHz, FIG. 3(f)), may be employed for mmW/THz generation and spectroscopy applications.

Characterisation of the expanded GS-OFC lines may be conducted in order to verify that the comb lines exhibit similar linewidth and are phase correlated. To do so, filter an individual line from the source OFC and the free running FP laser and measure their linewidths, then measure the linewidth of the expanded gain-switched FP lines. In the above examples the initial line widths for the source OFC and free running FP laser are 80 kHz and 750 kHz, respectively. Taking a representative line from four of the modes of the expanded gain switched OFC yields 90, 85, 85, and 90 kHz. The reduction in the linewidths is a clear indication of the efficient phase noise transfer between the source and the expanded FP OFC. Furthermore, to verify the level of phase correlation between expanded OFC lines, a pair of tones from two different modes (marked by red arrows in FIG. 3(f)), separated by frequencies between 6.25 and 37.5 GHz, are filtered and their RF beat tone measured. Plotting these indicates a 3 dB beat linewidth of 13 Hz, which clearly demonstrates a high level of phase correlation between the OFC lines.

In summary, exemplary embodiments for generating a wavelength tuneable broadband optical frequency comb have been described. It will be appreciated that the presently described techniques overcome many of the limitations of existing GSL OFCs. The presently described comb expansion technique can overcome the GSL problem with its comb bandwidth thereby making it well-suited (compared to competitive technologies) to be used in a wide range of applications.

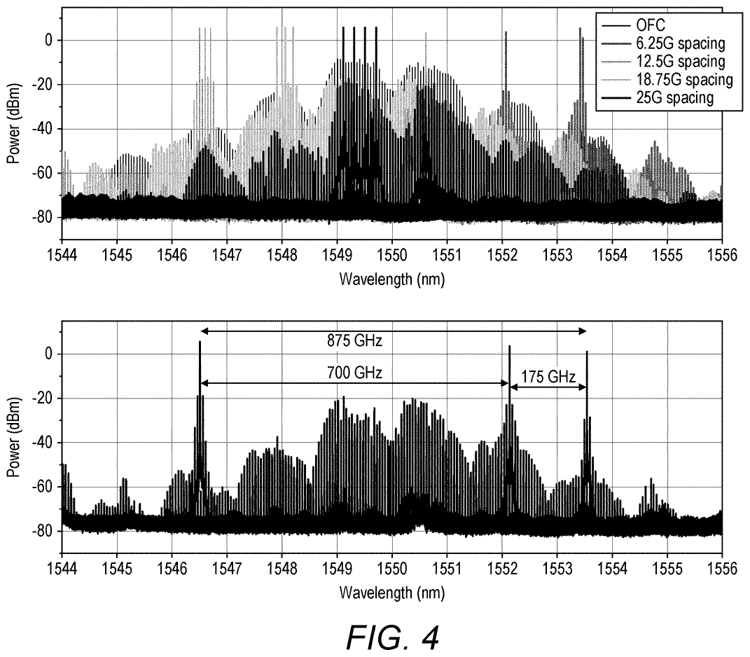

Particular advantages of the presently described OFC are:
The generation of highly correlated comb lines with spectral occupancy >875 GHz, which portrays low intensity, and phase noise properties.
The proposed technology is capable to reconfigure its emission wavelengths and FSR. The emission wavelength can be tuned by simultaneous injection locking desired set of discrete longitudinal modes, whereas FSR can be tuned by either changing gain-switching frequency or driving the PM at subharmonics of the FSR.
As shown in FIG. 4, comb lines within the 875 GHz bandwidth can be filtered and encoded with data to be transmitted. This demonstrates its suitability for both legacy WDM as well as next-generation superchannel-based networks with a desired channel separation.
A high degree of phase correlation between the comb lines is very attractive in generating high mmW and/or THz frequencies. As shown in FIG. 4, two lines separated by 875 GHz can be filtered and heterodyned on a photodiode to generate high-quality THz signal at 875 GHz.
Photonically integrate-able solution. Even though the schematic includes two more lasers (when compared to the EI GSL technique), it is quite simple to integrate them. Such integration could result in reducing cost, footprint, and energy consumption.

The described OFC may be manufactured industrially. An industrial application of the example embodiments will be clear from the discussion herein.

Although preferred embodiment(s) of the present invention have been shown and described, it will be appreciated by those skilled in the art that changes may be made without departing from the scope of the invention as defined in the claims.

Attention is directed to all papers and documents which are filed concurrently with or previous to this specification in connection with this application and which are open to public inspection with this specification, and the contents of all such papers and documents are incorporated herein by reference.

All of the features disclosed in this specification, and/or all of the steps of any method or process so disclosed, may be combined in any combination, except combinations where at least some of such features and/or steps are mutually exclusive.

Each feature disclosed in this specification may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification, or to any novel one, or any novel combination, of the steps of any method or process so disclosed.

1. An apparatus for generating a wavelength tuneable broadband optical frequency comb, comprising:
a master laser unit configured to generate a seed signal comprising a set of correlated tones; and
a gain switched slave laser configured to generate an optical output comprising multiple emission modes, and arranged to be seeded by the seed signal generated by the master laser unit,
wherein the seeding of the slave laser by the seed signal optically injection locks the emission modes of the slave laser unit to generate a coherent wideband optical frequency comb.

2. The apparatus of claim 1, wherein generating the coherent wideband optical frequency comb comprises exciting at least 2 longitudinal modes of the gain switched slave laser, preferably at least 6 longitudinal modes.

3. The apparatus of claim 1, wherein the master laser unit comprises a light source configured to generate an optical frequency comb.

4. The apparatus of claim 3, wherein the master laser unit comprises a dual-stage active demultiplexer configured to receive the optical frequency comb generated by the light source.

5. The apparatus of claim 4, wherein the dual-stage active demultiplexer comprises a first laser configured to receive the optical frequency comb generated by the light source, and a second laser configured to receive optical output from the first laser, and the seed signal comprises a number of spectral components based on a power of the first laser and second laser.

6. The apparatus of claim 5, wherein the set of correlated tones comprises amplified optical frequency comb tones and four wave mixed spectral tones.

7. The apparatus of claim 1, further comprising a phase modulator configured to receive the coherent wideband optical frequency comb to generate a substantially contiguous optical frequency comb.

8. The apparatus of claim 1, wherein the slave laser is a semiconductor laser.

9. A method of generating a wavelength tuneable broadband optical frequency comb, comprising:
generating an optical seed signal comprising a set of correlated tones;
generating a gain switched optical slave signal comprising multiple emission modes; and
injection locking the gain switched optical slave signal using the optical seed signal to generate a coherent wideband optical frequency comb.

10. The method of claim 9, wherein injection locking the gain switched optical slave signal using the optical seed signal to generate a coherent wideband optical frequency comb comprises exciting at least 2 longitudinal modes of the gain switched slave laser.

11. The method of claim 9, wherein generating the optical seed signal comprising the set of correlated tones comprises dual stage active demultiplexing of a frequency comb generated by a light source.

12. The method of claim 11, wherein the dual stage active demultiplexing comprises selecting and amplifying at least two comb tones of the optical frequency comb output by the light source.

13. The method of claim 12, wherein the dual stage active demultiplexing further comprises generating additional spectral components in the optical seed signal.

14. The method of claim 13, wherein the generating additional spectral components in the optical seed signal comprises generating the spectral components by four wave mixing.

15. The method of claim 12, wherein the selected and amplified at least two comb tones are selected based on a mode separation frequency of the gain-switched optical slave signal.

16. The method of claim 15, wherein a separation of the selected and amplified at least two comb tones substantially matches the mode separation frequency of the optical slave signal.

17. The method of claim 15, further comprising optimising the separation of the selected and amplified at least two comb tones with respect to the mode separation frequency of the optical slave signal to generate a flattened optical frequency comb.

18. The method of claim 9, further comprising making the coherent wideband optical frequency comb more contiguous.

19. A photonic circuit comprising the apparatus of claim 1 and/or configured to operate the method of generating a wavelength tuneable broadband optical frequency comb, comprising:
generating an optical seed signal comprising a set of correlated tones;
generating a gain switched optical slave signal comprising multiple emission modes; and
injection locking the gain switched optical slave signal using the optical seed signal to generate a coherent wideband optical frequency comb.
